(19) United States
(12) Patent Application Publication
(10) Pub. No.: US 2011/0041769 A1
(43) Pub. Date: Feb. 24, 2011

(54) APPARATUS FOR CHEMICAL VAPOR DEPOSITION AND APPARATUS FOR PROCESSING SUBSTRATE

(75) Inventor: Jae Moo Lee, Pyeongtaek (KR)

Correspondence Address: EDWARDS ANGELL PALMER & DODGE LLP, P.O. BOX 55874, BOSTON, MA, 02205, US

(73) Assignee: LIGADP CO., LTD, Seongnam (KR)

(21) Appl. No.: 12/845,154

(22) Filed: Jul. 28, 2010

(30) Foreign Application Priority Data
Jul. 28, 2009 (KR) 10-2009-0068830

(51) Int. Cl. C23C 16/00

(52) U.S. Cl. 118/733

(57) ABSTRACT

Provided are a chemical vapor deposition (CVD) apparatus and a substrate processing apparatus. The CVD apparatus includes a chamber defining a processing chamber for forming a thin film on a substrate, a shower head that discharges processing gas into the processing chamber, a lid for opening and closing the chamber, a hinge part that pivotably couples the lid to the chamber at one side of the lid, a clamping part is provided to press the other side of the lid to secure the lid to the chamber, and a control part adapted to raise or lower the one side of the lid when the clamping part is pressing the other side of the lid.

### CROSS-REFERENCE TO RELATED PATENT APPLICATION

This application claims the benefit of Korean Application No. 10-2009-0068830, filed on Jul. 28, 2009, the disclosure of which is incorporated herein in its entirety by reference.

### BACKGROUND

1. Technical Field

The present disclosure relates to a chemical vapor deposition (CVD) apparatus and a substrate processing apparatus, and more particularly, to a CVD apparatus that can form a thin film on a substrate and a substrate processing apparatus that can perform a predetermined process on a substrate.

2. Related Art

In the manufacturing of a light emitting diode (LED), various processes including an epitaxial process, a fabrication process, a packaging (PKG) process, and so forth are applied. The epitaxial process is used to growing a crystalline film on a substrate using a metal organic chemical vapor deposition (MOCVD) apparatus.

A typical MOCVD apparatus includes a chamber, a shower head, and a susceptor. The chamber holds therein a substrate for processing. A lid is pivotably mounted to an upper part of the chamber to open and close the substrate processing chamber by pivotal movement on the chamber. The shower head is coupled to the lid to be able to pivot in concert with the lid. The shower head discharges processing gas into the chamber. The susceptor supports the substrate within the chamber.

The pivotal movement of the lid enables loading/unloading of the substrate. That is, the lid pivotably moves in the opening direction on the chamber to open the processing chamber. The substrate is then loaded in the processing chamber and supported on the susceptor. The lid is then pivotably moved in the closing direction to seal the processing chamber.

Here, the lid is combined with the chamber by means of a clamp in order to maintain a tight seal of the processing chamber. Consequently, pressure is applied to the one side of the lid on which the clamp is installed. The lid may be tilted toward one side due to the pressure exerted by the clamp.

When the lid is tilted toward one side, the tight seal of the processing chamber may not be maintained. Also, the shower head coupled to the lid may be tilted together with the lid. If the shower head is tilted, the distance between the shower head and the substrate becomes non-uniform. Accordingly, the thickness of a thin film formed by the apparatus becomes non-uniform, thereby causing the quality of the final LED product to be deteriorated.

The above information disclosed in this Background section is only for enhancement of understanding of the background of the invention and therefore it may contain information that does not form the prior art that is already known in this country to a person of ordinary skill in the art.

### SUMMARY OF THE DISCLOSURE

The present invention provides a CVD apparatus and a substrate processing apparatus that facilitate tilt control of a lid thereof.

In one aspect, the present invention provides an apparatus for chemical vapor deposition (CVD). The apparatus comprises a chamber, a lid, a shower head, a hinge part, a clamping part, and a tilt control part. The chamber function s to hold a substrate therein. The lid is pivotably attached by the hinge part to the chamber for opening and closing the chamber. The shower head is coupled to an inner surface of the lid oriented toward an inside of the chamber and has a plurality of discharging holes for discharging processing gas into the chamber. The clamping part is provided to press the other side of the lid to secure the lid to the chamber. The tilt control part is provided to raise or descend the one side of the lid to control tilt of the lid, with the other side of the lid being pressed by the clamping part.

Preferably, the hinge part may comprise a pivot plate which is separate from and disposed above the lid. One end of the pivot plate is hinge-coupled to the chamber and the other end thereof is hinge-coupled to the lid. Suitably, the tilt control part may comprise a control screw passing through and fastened to the pivot plate for pressing against the one side of the lid. Also suitably, the tilt control part may comprise a resilient member disposed between the pivot plate and the lid for resiliently support the pivot plate.

Preferably, the hinge part may comprise a pivot cylinder for providing driving force used for pivoting the lid and a pivot link connecting the pivot cylinder and the lid for converting linear motion of the pivot cylinder to rotational motion.

Preferably, the clamping part may comprise a housing disposed outside the chamber, a clamp hinge-coupled to the housing, a securing cylinder disposed inside the housing for providing driving force used for pivoting the clamp, a securing link connecting the securing cylinder and the clamp for converting linear motion of the securing cylinder to rotational motion, and a pressing link adapted to press the securing link.

Preferably, the hinge part and the tilt control part each may be provided in plurality and respectively spaced from each other at one side of the lid.

In another aspect, the present invention provides an apparatus for substrate processing. The apparatus comprises a chamber holding a substrate therein, a lid for opening and closing the chamber, a hinge part pivotably coupling the lid at one side of the lid to the chamber, a clamping part adapted to press the other side of the lid to secure the lid to the chamber, and a tilt control part adapted to raise or descend the one side of the lid to control tilt of the lid, with the other side of the lid being pressed by the clamping part.

Preferably, the hinge part may comprise a pivot plate which is separate from and disposed above the lid, one end of the pivot plate being hinge-coupled to the chamber and the other end being hinge-coupled to the lid. Suitably, the tilt control part may comprise a control screw passing through and fastened to the pivot plate for pressing against the one side of the lid. Also suitably, the tilt control part may further comprise a resilient member disposed between the pivot plate and the lid for resiliently supporting the pivot plate.

Preferably, the hinge part may comprise a pivot cylinder for providing driving force used for pivoting the lid and a pivot link connecting the pivot cylinder and the lid for converting linear motion of the pivot cylinder to rotational motion.

Preferably, the clamping part may comprise a housing disposed outside the chamber, a clamp hinge-coupled to the housing, a securing cylinder disposed inside the housing for providing driving force used for pivoting the clamp, a securing link connecting the securing cylinder and the clamp for converting linear motion of the securing cylinder to rotational motion, and a pressing link adapted to press the securing link.

Preferably, the hinge part and the tilt control part each may be provided in plurality and respectively spaced from each other at one side of the lid.

The above and other features and advantages of the present invention will be apparent from or are set forth in more detail in the accompanying drawings, which are incorporated in and form a part of this specification, and the following Detailed Description, which together serve to explain by way of example the principles of the present invention.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view of a CVD apparatus according to an exemplary embodiment of the present invention;

FIG. 2 is a perspective view of the CVD apparatus of FIG. 1;

FIG. 3 is an operational view of the CVD apparatus of FIG. 1, which shows the state of the processing chamber thereof being opened; and

FIGS. 4A to 5B are operational views showing tilt control of the lid of the CVD apparatus of FIG. 1.

### DETAILED DESCRIPTION OF DISCLOSURE

Reference will now be made in detail to the preferred embodiment of the present invention, examples of which are illustrated in the drawings attached hereinafter, wherein like reference numerals refer to like elements throughout. The embodiments are described below so as to explain the present invention by referring to the figures.

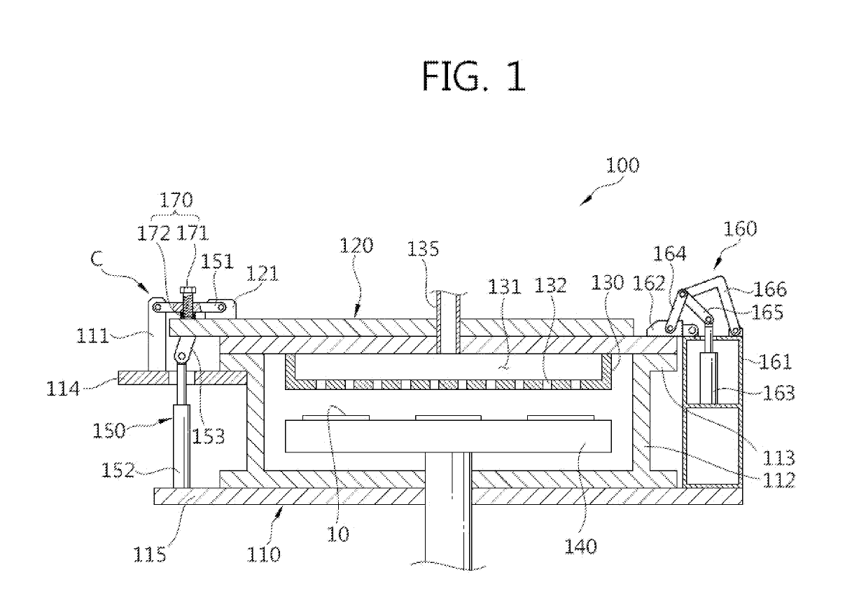

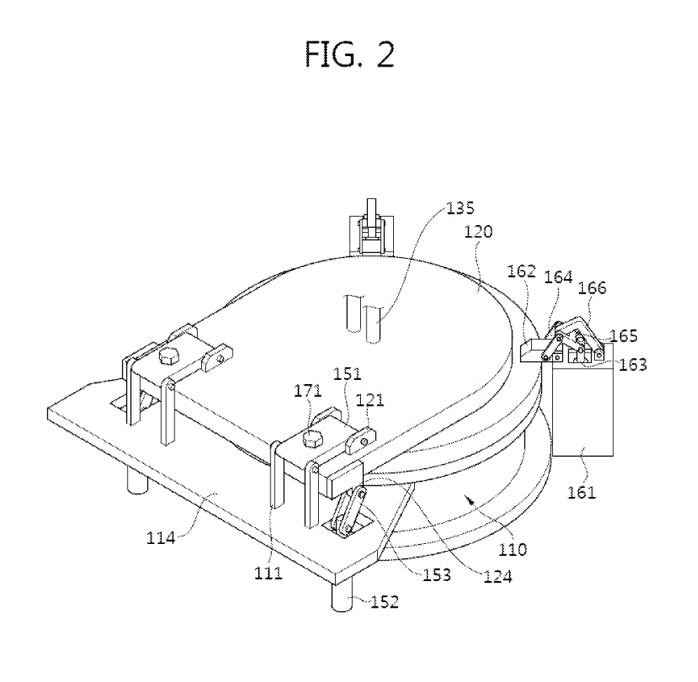

FIG. 1 is a sectional view of a CVD apparatus according to an exemplary embodiment of the present invention, and FIG. 2 is a perspective view of the CVD apparatus of FIG. 1.

Referring to FIGS. 1 and 2, the CVD apparatus 100 includes a chamber 110, a lid 120, a shower head 130, a hinge part 150, a clamping part 160, and a tilt control part 170.

The chamber 110 is provided to hold therein a substrate 10 to be processed. The lid 120 is disposed at the top of the chamber 110.

The hinge part 150 is disposed on one side of the lid 120. The hinge part 150 enables the lid 120 to pivot with respect to the chamber 110. The hinge part 150 includes a pivot plate 151, a pivot cylinder 152, and a pivot link 153.

The pivot plate 151 is separate from and disposed above the lid 120. One end of the pivot plate 151 is hinge-coupled to a first supporter 111 projecting from a sidewall of the chamber 110. The other end of the pivot plate 151 is hinge-coupled to a second supporter 121 projecting from the top surface of the lid 120. Accordingly, the one end of the pivot plate 151 can pivot at the sidewall of the chamber 110, and the other end of the pivot plate 151 can pivot at the top surface of the lid 120.

The pivot cylinder 152 is disposed at one side of the lower portion of the lid 120. The pivot cylinder 152 provides driving force used to pivot the lid 120 with respect to the chamber 110.

The pivot link 153 is disposed between the pivot cylinder 152 and the lid 120. One end of the pivot link 153 is hinge-coupled to a rod of the pivot cylinder 152. The other end of the pivot link 153 is hinge-coupled to a side surface of the lid 120. The pivot link 153 is provided to convert the linear motion of the pivot cylinder 152 into rotational motion to pivot the lid 120 with respect to the chamber 110.

The thus-configured hinge part 150 is provided as a pair.

The clamping part 160 is disposed at the other side of the lid 120. The clamping part 160 functions to maintain a tight seal inside the chamber 110 by securing the other side of the lid 120 to the chamber 110. The clamping part 160 includes a housing 161, a clamp 162, a securing cylinder 163, a first securing link 164, and a second securing link 165.

The housing 161 is disposed at the other side of the lid 120. The clamp 162 is hinge-coupled at the top of the housing 161 such that it can pivot at the top of the housing 161. The securing cylinder 163 is disposed inside the housing 161. The securing cylinder 163 provides driving force used to pivot the clamp 162 so that the clamp 162 presses against the lid 120. The first securing link 164 and the second securing link 165 are disposed between the clamp 162 and the securing cylinder 163. One end of the first securing link 164 is hinge-coupled to the clamp 162. The other end of the first securing link 164 is hinge-coupled to one end of the second securing link 165. The other end of the second securing link 165 is hinge-coupled to a rod of the securing cylinder 163. The first securing link 164 and the second securing link 165 function to convert the linear motion of the securing cylinder 163 to rotational motion to pivot the clamp 162 at the housing 161.

A pressing link 166 is connected to a pin that connects the first securing link 164 and the second securing link 165. The pressing link 166 is provided to press the pin connecting the first securing link 164 and the second securing link 165.

The thus-configured clamping part 160 is provided as a pair at positions opposite the pair of the hinge parts 150, respectively.

As described above, the lid 120 is able to be pivotably moved with respect to the chamber 110 while being secured to the chamber 110 at one side thereof by the hinge part 150. Also, the lid 120 is secured by means of the clamping part 160 to the chamber 110.

The tilt control part 170 is provided to control the tilt of the lid 120 to keep the lid 120 flat. The tilt control part 170 includes a control screw 171 and a resilient member 172.

The control screw 171 is fastened to the pivot plate 151 and passes through the pivot plate 151. The terminal end of the control screw 171 passing through the pivot plate 151 presses against the lid 120. The tilt of the lid 120 may be controlled by controlling the number of turns of the control screw 171. The resilient member 172 is disposed between the pivot plate 151 and the lid 120. The resilient member 172 is configured as a compression spring that encloses the outer periphery of the control screw 171 and functions to resiliently support the pivot plate 151 from the lid 120.

The thus-configured tilt control part 170 is provided as a pair, which are fastened to the pair of the pivot plates 151, respectively.

The shower head 130 is coupled to the one side of the lid 120 oriented toward the inside of the chamber 110. The showerhead 130 can be moved by pivotal movement of the lid 120. A diffusion chamber 131 for diffusing processing gas is defined within the shower head 130. A plurality of discharge holes 132 is defined in the one side of the shower head 130 oriented toward the inside of the chamber 110. The plurality of discharge holes 132 discharges processing gas diffused in the diffusion chamber 131 uniformly into the processing chamber. A supply conduit 135 for supplying processing gas is connected to the opposite side of the shower head 130 oriented toward the outside of the chamber 110. The supply conduit 135 is communicated with the diffusion chamber 131 from the outside of the chamber 110 through the lid 120.

The susceptor 140 is disposed inside the chamber 110. The susceptor 140 functions to support the substrate 10 within the chamber 110. While not shown, heating means such as a heating coil for heating the substrate 10 may be installed within the susceptor 140.

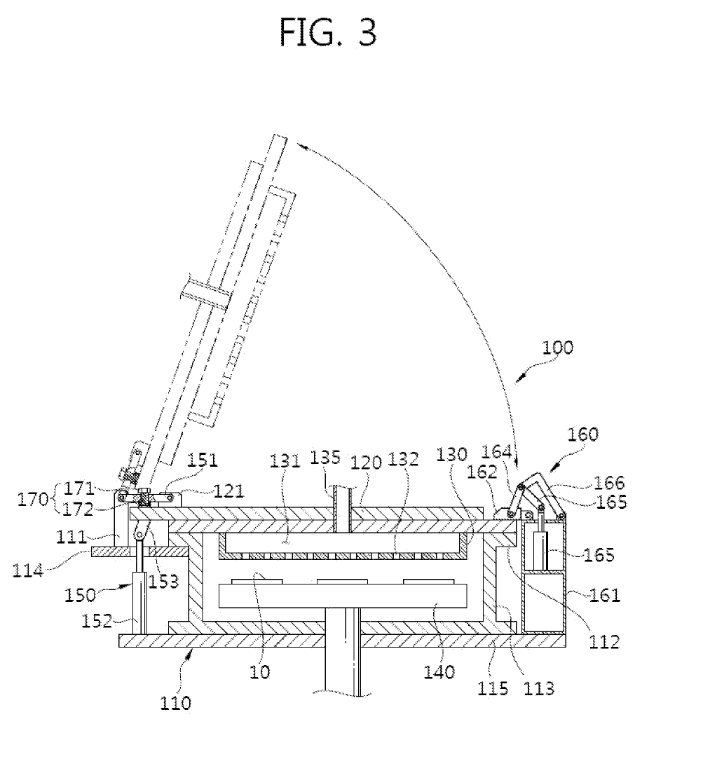

The lid tilt control operation of a CVD apparatus according to an embodiment of the present invention will be described in detail with reference to FIG. 3 to FIG. 5B.

FIG. 3 is an operational view of the CVD apparatus of FIG. 1, which shows the state of the processing chamber thereof being opened.

Referring to FIG. 3, when the lid 120 is pivotably moved in the opening direction, the chamber 110 becomes open. The substrate 10 can be loaded from the outside into the chamber 110 and supported by the susceptor 140.

On the other hand, when the lid 120 is pivotably moved in the closing direction, the chamber 110 becomes closed and can be sealed. That is, the pivot cylinder 152 lowers the rod. The pivot link 153 converts the linear motion of the pivot cylinder 152 to rotational motion. The lid 120 is pivoted by the pivot link 153 and seated atop the chamber 110. Here, the shower head 130 can be moved by the pivotal movement of the lid 120 and positioned within the chamber 110.

Then, in order to maintain the seal of the inside of the chamber 110, the clamping part 160 presses the other side of the lid 120 to secure the lid 120 to the chamber 110. That is, the securing cylinder 163 elevates the rod. The first securing link 164 and the second securing link 165 convert the linear motion of the securing cylinder 163 to rotational motion. The clamp 162 is pivoted by means of the first securing link 164 and the second securing link 165 and contacted with the upper surface of the lid 120. Here, the pressing link 166 presses and supports the pin connecting the first securing link 164 and second securing link 165.

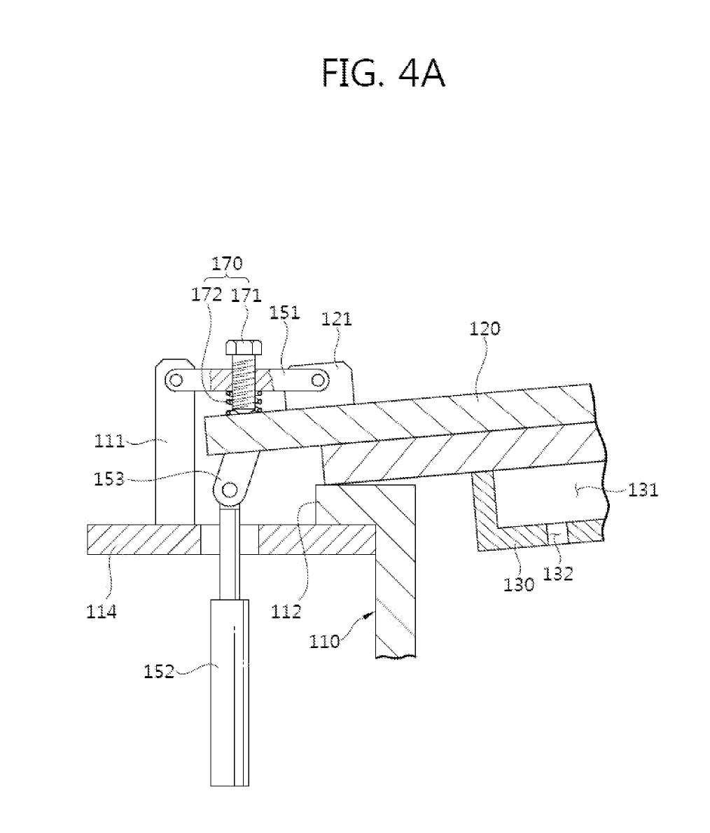

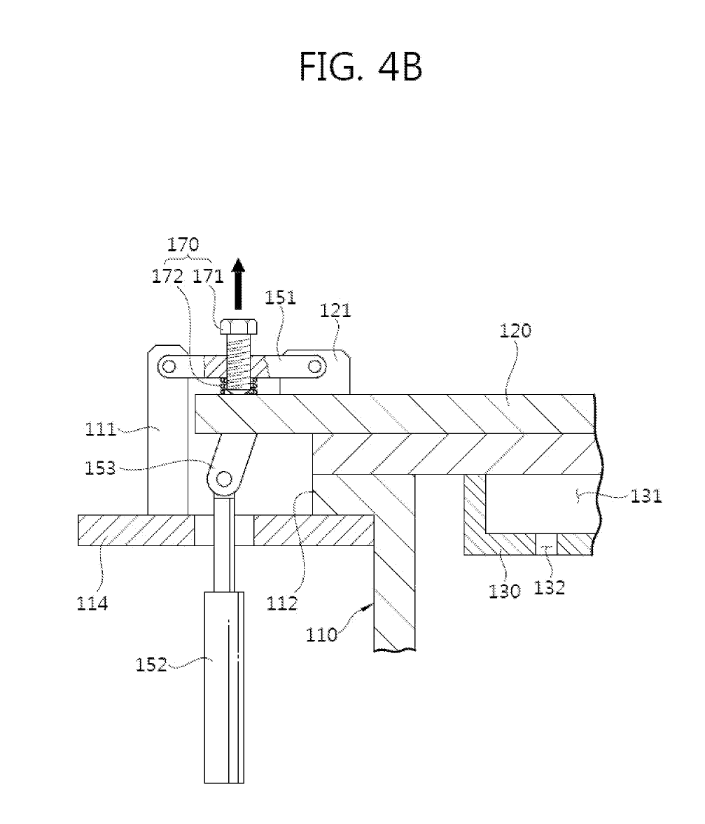

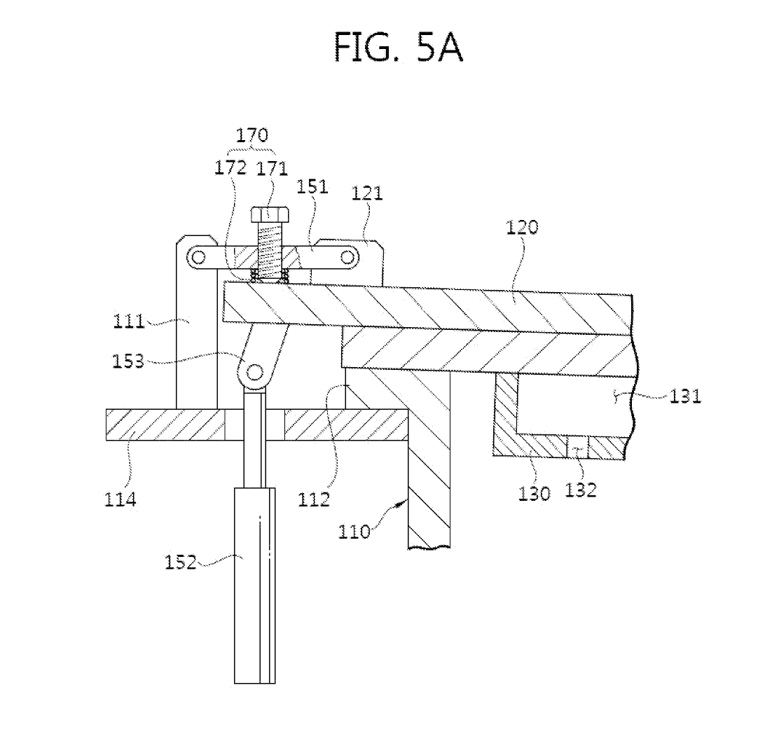

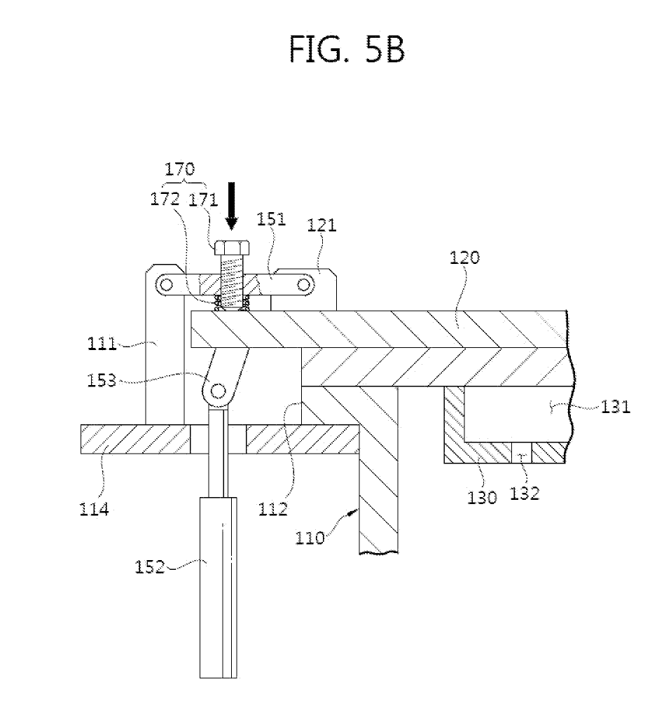

FIGS. 4A to 5B are operational views showing tilt control of the lid 120 of the CVD apparatus of FIG. 1.

Referring to FIGS. 4A to 5B, the lid 120 may be tilted by means of pressure exerted by the clamping part 160 on the other side of the lid 120.

The pressure exerted by the clamping part 160 on the other side of the lid 120 may be weaker than the supporting force of the hinge part 150 on the opposite one side of the lid 120. In this case, the lid 120 may be tilted upward at the other side. Here, the control screw 171 is loosened to control the tilt of the lid 120. When the control screw 171 is loosened, the one side of the lid 120 is raised due to the pressure exerted by the clamping part 160 on the other side of the lid 120.

Conversely, the pressure exerted on the other side of the lid 120 by the clamping part 160 may be stronger than the supporting force on the one side of the lid 120 by the hinge part 150. In this case, the lid 120 may be tilted downward at the other side. Here, the tilt of the lid 120 is controlled by tightening the control screw 171. When the control screw 171 is tightened, the one side of the lid 120 is pressed and lowered by the control screw 171.

Thus, the tilt of the lid 120 may be controlled by controlling the number of turns of the control screw 171. Accordingly, the tilt of the shower head 130 coupled to the one side of the lid 120 may also be controlled.

As described above, the hinge part 150 and the tilt control part 170 are provided in pairs apart from each other, respectively. Accordingly, by controlling the number of turns of the pair of control screws 171, the lid 120 may be controlled in its tilt, which tilts in the direction of the gaps between the hinge parts 150 and the tilt control parts 170.

Thus, the CVD apparatus 100 is able to uniformly seal the processing chamber, and a thin film may be formed at a uniform thickness on a substrate 10.

In addition to the CVD apparatus 100, the above-described hinge part 150, clamping part 160, and tilt control part 170 may be used in other apparatuses used for substrate 10 processing, such as spin-coating apparatuses, ion implantation apparatuses, and plasma treatment apparatuses, for opening and closing a processing chamber and controlling the tilt of a lid 120.

A CVD apparatus and substrate processing apparatus according to the present invention can control the tilt of a lid in order to firmly maintain the seal of a processing chamber.

Also, a CVD apparatus according to the present invention can control the tilt of a shower head in order to form a thin film at a uniform thickness on a substrate.

While the present invention has been particularly shown and described with reference to exemplary embodiments thereof, it will be understood by those of ordinary skill in the art that various changes in form and details may be made therein without departing from the spirit and scope of the present invention as defined by the following claims. Therefore, future modifications to the embodiments of the present invention cannot depart from the technical scope of the present invention.

What is claimed is:

1. An apparatus for chemical vapor deposition (CVD), comprising:
a chamber holding a substrate therein;
a lid for opening and closing the chamber;
a shower head coupled to an inner surface of the lid oriented toward an inside of the chamber and having a plurality of discharging holes for discharging processing gas into the chamber;
a hinge part pivotably coupling the lid at one side of the lid to the chamber;
a clamping part adapted to press the other side of the lid to secure the lid to the chamber; and
a tilt control part adapted to raise or descend the one side of the lid to control tilt of the lid, with the other side of the lid being pressed by the clamping part.

2. The apparatus for CVD of claim 1, wherein the hinge part comprises a pivot plate which is separate from and disposed above the lid, one end of the pivot plate being hinge-coupled to the chamber and the other end being hinge-coupled to the lid.

3. The apparatus for CVD of claim 2, wherein the tilt control part comprises a control screw passing through and fastened to the pivot plate for pressing against the one side of the lid.

4. The apparatus for CVD of claim 3, wherein the tilt control part further comprises a resilient member disposed between the pivot plate and the lid for resiliently support the pivot plate.

5. The apparatus for CVD of claim 1, wherein the hinge part comprises:
a pivot cylinder for providing driving force used for pivoting the lid; and
a pivot link connecting the pivot cylinder and the lid for converting linear motion of the pivot cylinder to rotational motion.

6. The apparatus for CVD of claim 1, wherein the clamping part comprises:
a housing disposed outside the chamber;
a clamp hinge-coupled to the housing;
a securing cylinder disposed inside the housing for providing driving force used for pivoting the clamp;
a securing link connecting the securing cylinder and the clamp for converting linear motion of the securing cylinder to rotational motion; and
a pressing link adapted to press the securing link.

7. The apparatus for CVD of claim 1, wherein the hinge part and the tilt control part each are provided in plurality and respectively spaced from each other at one side of the lid.

8. An apparatus for substrate processing, comprising:
a chamber holding a substrate therein;
a lid for opening and closing the chamber;
a hinge part pivotably coupling the lid at one side of the lid to the chamber;
a clamping part adapted to press the other side of the lid to secure the lid to the chamber; and
a tilt control part adapted to raise or descend the one side of the lid to control tilt of the lid, with the other side of the lid being pressed by the clamping part.

9. The apparatus for substrate processing of claim 8, wherein the hinge part comprises a pivot plate which is separate from and disposed above the lid, one end of the pivot plate being hinge-coupled to the chamber and the other end being hinge-coupled to the lid.

10. The apparatus for substrate processing of claim 9, wherein the tilt control part comprises a control screw passing through and fastened to the pivot plate for pressing against the one side of the lid.

11. The apparatus for substrate processing of claim 10, wherein the tilt control part further comprises a resilient member disposed between the pivot plate and the lid for resiliently supporting the pivot plate.

12. The apparatus for substrate processing of claim 8, wherein the hinge part comprises:
a pivot cylinder for providing driving force used for pivoting the lid; and
a pivot link connecting the pivot cylinder and the lid for converting linear motion of the pivot cylinder to rotational motion.

13. The apparatus for substrate processing of claim 8, wherein the clamping part comprises:
a housing disposed outside the chamber;
a clamp hinge-coupled to the housing;
a securing cylinder disposed inside the housing for providing driving force used for pivoting the clamp;
a securing link connecting the securing cylinder and the clamp for converting linear motion of the securing cylinder to rotational motion; and
a pressing link adapted to press the securing link.

14. The apparatus for substrate processing of claim 8, wherein the hinge part and the tilt control part each are provided in plurality and respectively spaced from each other at one side of the lid.
